(19) United States
(12) Patent Application Publication
(10) Pub. No.: US 2025/0022726 A1
(43) Pub. Date: Jan. 16, 2025

(54) AIRFLOW CONTROL METHOD FOR AIR FLOTATION CYCLONE OPERATION OF LOW-PRESSURE HEAT TREATMENT DEVICE

(71) Applicant: Beijing E-Town Semiconductor Technology Co., Ltd., Beijing (CN)

(72) Inventors: Jianmin JI, Beijing (CN); Haiwei LI, Beijing (CN); Shichao XIA, Beijing (CN)

(21) Appl. No.: 18/764,808

(22) Filed: Jul. 5, 2024

(30) Foreign Application Priority Data
Jul. 14, 2023 (CN) 202310871695.X

(51) Int. Cl. H01L 21/67; H01L 21/324

(52) U.S. Cl. CPC H01L 21/67109; H01L 21/324

(57) ABSTRACT

Provided is an airflow control method for an air flotation cyclone operation of a low-pressure heat treatment device, comprising: arranging a pressure sensor in a process chamber of the low-pressure heat treatment device, and controlling a pressure of process gas in the process chamber to be 1 to 20 Torrs; controlling a flow rate of cyclone gas delivered toward a bottom surface of a tray of the low-pressure heat treatment device to be 0.5 to 1.5 L/min by flow control, and controlling accuracy to be within ±0.2 L/min; and adjusting the flow rate of the cyclone gas so that the tray and a semiconductor workpiece placed on an upper surface of the tray rotate together.

### CROSS-REFERENCE TO RELATED APPLICATIONS

The present application claims priority to Chinese Patent Application No. CN202310871695.X, filed with the China National Intellectual Property Administration on Jul. 14, 2023, the disclosure of which is hereby incorporated herein by reference in its entirety.

### TECHNICAL FIELD

The present disclosure relates to the field of semiconductor manufacturing, and in particular to an airflow control method for an air flotation cyclone operation of a low-pressure heat treatment device.

### BACKGROUND

The rapid thermal annealing device is an essential workstage in the wafer manufacturing process. The temperature of the annealing process is usually 200 to 1250° C., and the time of the annealing process is usually tens of seconds. The temperature uniformity of all areas on the entire wafer is crucial. In practical applications, it is easy to cause uneven local temperatures on the wafer due to slight differences in the functions of the heating lamps, differences in the parallelism of the wafer and the lamps, and local differences inside the reaction chamber, etc. Therefore, the annealing device needs to be rotated during the process to achieve the uniformity of the annealing temperature on the entire wafer.

### SUMMARY

The present disclosure provides an airflow control method for enabling a tray of a heat treatment device to perform an air flotation cyclone operation under a low pressure environment.

According to one aspect of the present disclosure, provided is an airflow control method for an air flotation cyclone operation of a low-pressure heat treatment device, including:
arranging a pressure sensor in a process chamber of the low-pressure heat treatment device, and controlling a pressure of process gas in the process chamber to be 1 to 20 Torrs;
controlling a flow rate of cyclone gas delivered toward a bottom surface of a tray of the low-pressure heat treatment device to be 0.5 to 1.5 L/min by flow control, and controlling accuracy to be within ±0.2 L/min; and
adjusting the flow rate of the cyclone gas so that the tray and a semiconductor workpiece placed on an upper surface of the tray rotate together.

The airflow control method according to the present disclosure enables the tray and the semiconductor workpiece thereon to stably rotate together by precisely controlling the flow rate of the cyclone gas.

It should be understood that the content described in this part is not intended to identify critical or essential features of embodiments of the present disclosure, nor is it used to limit the scope of the present disclosure. Other features of the present disclosure will be easily understood through the following description.

### BRIEF DESCRIPTION OF THE DRAWINGS

The accompanying drawings are used to better understand the present solution, and do not constitute a limitation to the present disclosure.

FIG. 1 is a side view of a structure of an air flotation cyclone system inside a process chamber of a low-pressure heat treatment device according to an embodiment of the present disclosure; and

FIG. 2 is a top view of a structure of an air flotation cyclone system inside a process chamber of a low-pressure heat treatment device according to an embodiment of the present disclosure.

### DETAILED DESCRIPTION

Hereinafter, descriptions to exemplary embodiments of the present disclosure are made with reference to the accompanying drawings, include various details of the embodiments of the present disclosure to facilitate understanding, and should be considered as merely exemplary. Therefore, those having ordinary skill in the art should realize, various changes and modifications may be made to the embodiments described herein, without departing from the scope of the present disclosure. Likewise, for clarity and conciseness, descriptions of well-known functions and structures are omitted in the following descriptions.

The current annealing device uses a normal pressure process, the wafer rotation uses gas to suspend the wafer, and the gas drives the tray of the wafer to rotate so that the wafer rotates during the process. The rotating gas of the tray of the wafer performs real-time data collection, feedback and adjustment during the process, and performs closed-loop control to meet the stability requirement of the wafer rotation.

The low-pressure annealing device, such as remote plasma oxidation device (RPO) or low-pressure free radical oxidation device (LP), is a high-temperature annealing device. For the low-pressure annealing process, on the one hand, the very high temperature uniformity is required; and on the other hand, the wafer needs to be rotated during the process, to meet the process uniformity requirement. Therefore, it is necessary to invent a way to rotate the wafer under the low-pressure condition (1 to 20 Torrs).

The present disclosure provides an airflow control method for an air flotation cyclone operation of a low-pressure heat treatment device, and this method controls the movement of the air flotation cyclone component by accurately controlling the flow rate of the cyclone gas.

According to one specific embodiment, there is provided an airflow control method for an air flotation cyclone operation of a low-pressure heat treatment device, including:
arranging a pressure sensor in a process chamber of the low-pressure heat treatment device, and controlling a pressure of process gas in the process chamber to be 1 to 20 Torrs;
controlling a flow rate of cyclone gas delivered toward a bottom surface of a tray of the low-pressure heat treatment device to be 0.5 to 1.5 L/min by flow control, and controlling accuracy to be within ±0.2 L/min; and
adjusting the flow rate of the cyclone gas so that the tray and a semiconductor workpiece placed on an upper surface of the tray rotate together.

According to one embodiment, the cyclone gas may be nitrogen, or oxygen, or a mixture of hydrogen and oxygen. Preferably, when the cyclone gas is a mixture of hydrogen and oxygen, the flow ratio of hydrogen is less than 33% and not zero; and the flow ratio of oxygen is greater than 67% and less than 100%.

In the low-pressure heat treatment process, due to the low pressure in the process chamber, the process gas may include hydrogen used to promote the formation of oxygen free radicals and prolong the retention time of the oxygen free radicals. According to one embodiment, the process gas may be, for example, a mixed gas of hydrogen and oxygen. More preferably, the flow ratio of hydrogen is less than 33% (e.g., less than 25%, less than 20%, less than 18%, less than 10%, less than 5%), and is not zero; and the flow ratio of oxygen is greater than 67% (e.g., greater than 75%, greater than 80%, greater than 87%, greater than 95%), and is less than 100%. For safety reasons, the hydrogen component in the process gas can only be introduced when the pressure in the process chamber is below 20 Torrs.

The cyclone gas preferably has the same composition as the process gas to avoid the introduction of excess gas.

According to one embodiment, when the low-pressure heat treatment device is a remote plasma oxidation treatment device, the pressure in the process chamber is controlled to be within a range of 1 to 8 Torrs (for example, 3 Torr, 5 Torr, 6 Torr, 7 Torr) by the pressure sensor, the flow rate of the cyclone gas is controlled to be within a range of 0.5 to 1 L/min (for example, 0.6 L/min, 0.7 L/min, 0.8 L/min, 0.9 L/min) by a flow controller, and the accuracy is controlled to be within ±0.1 L/min.

According to another embodiment, when the low-pressure heat treatment device is a low-pressure free radical oxidation treatment device, the pressure in the process chamber is controlled to be within a range of 5 to 15 Torrs by the pressure sensor, the flow rate of the cyclone gas is controlled to be within a range of 0.5 to 1.5 L/min by a flow controller, and the accuracy is controlled to be within ±0.2 L/min.

Further, the total flow rate of the process gas is within a range of 1 to 60 slm (Standard Liter per Minute), preferably 5 to 50 slm, for example, 16 slm, 20 slm, 30 slm, 45 slm.

Under all conditions of the process gas and the cyclone gas described above, the rotation speed of the semiconductor workpiece may be 40 to 100 revolutions per minute, preferably 60 revolutions per minute.

According to one embodiment, in the airflow control method of the present disclosure, the cyclone gas delivered toward the bottom surface of the tray of the low-pressure heat treatment device includes the cyclone gas delivered in one or both of a clockwise direction and a counterclockwise direction, to accelerate or decelerate the rotation of air flotation.

The flow rate and pressure of the process gas and flotation gas need to meet the above-mentioned range and accuracy. If the flow rate of the process gas is too large, the pressure in the process chamber will be too high, posing a safety hazard; if the flow rate is too low, the amount of gas in the process chamber will be too small, reducing the process uniformity. If the flow rate of the flotation gas is too high, the movement stability of the air flotation cyclone system will be reduced; if the flow rate of the flotation gas is too low, it will be difficult to rotate the tray and wafer effectively.

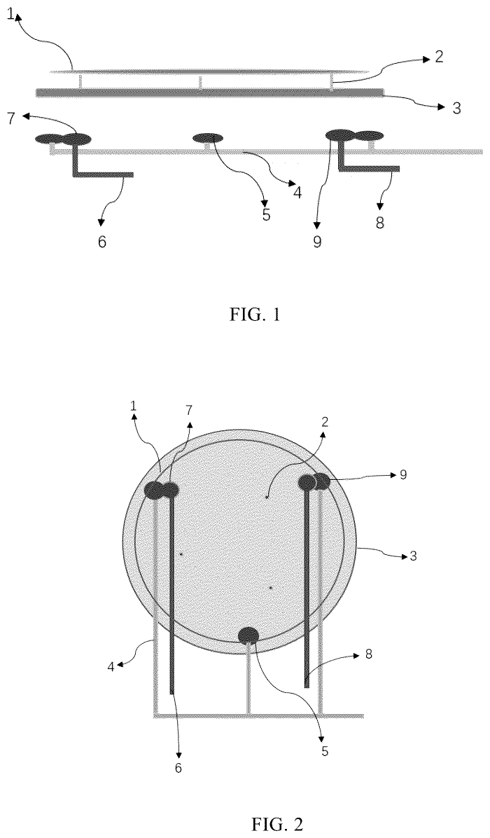

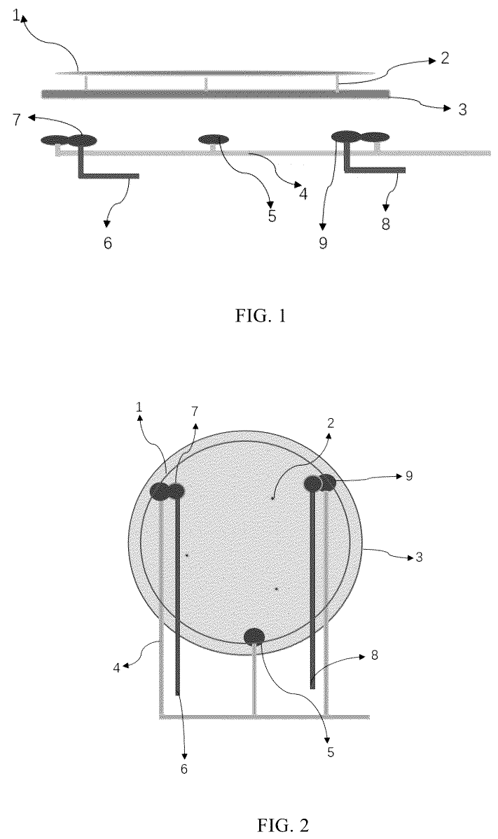

Referring to FIGS. 1 and 2, the air flotation cyclone system for the low-pressure heat treatment device of the present disclosure may include: a tray 3, optionally a plurality of support needles 2 located on an upper surface of the tray and configured to support the back side of a wafer 1, a flotation gas pipeline 4, flotation gas outlets 5 (which may include 3 or more outlets), an accelerating flotation gas pipeline 6, an accelerating flotation gas outlet 7, a decelerating flotation gas pipeline 8, and a decelerating flotation gas outlet 9.

The flotation gas is sprayed from the gas outlets 5 to the bottom surface of the tray through the pipeline 4, and can cause the tray to suspend and rotate. The accelerating flotation gas is sprayed from the gas outlet 7 through the pipeline 6 to accelerate the rotation of the tray in the forward direction (or first direction). The decelerating flotation gas is sprayed from the gas outlet 9 through the pipeline 8 to cause the tray to rotate in the reverse direction (or the second direction opposite to the first direction), thereby reducing the speed of the forward rotation.

The air flotation cyclone system may further include: a flotation gas control valve configured to control the intake flow of the flotation gas and respectively located on the input pipeline of the flotation gas; and a detection element configured to detect the movement state of the tray and the wafer.

Under the action of the air flotation cyclone system, the tray can be suspended and rotated, and the wafer thereon can move synchronously with the tray and always remain close to the upper surface of the tray. The suspension, rotation and stop movement of the tray may drive the wafer to perform the same suspension, rotation and stop movement. That is, the tray remains stationary relative to the wafer during the entire movement process.

As can be seen from the above, the normal pressure device (760 Torrs) uses the wafer rotation method of gas flotation cyclone, and the wafer rotation method of gas flotation cyclone can meet the process requirements and also meet the requirement of process stability. Specifically, the flow rate of the cyclone gas in the normal pressure device is usually within the range of 8 to 15 L/min, and the cyclone gas is usually nitrogen or oxygen. Since the pressure is relatively large, the cyclone gas cannot be hydrogen. The pressure of the process chamber is 760 Torrs, and no pressure control or pressure sensor is required.

Compared with the normal pressure device (760 Torrs), the pressure in the process chamber of the low-pressure device (1 to 20 Torrs) is greatly reduced due to the small amount of gas in the process chamber. Therefore, it is a great challenge to maintain the stable rotation and stability of the tray and wafer during the rotational movement. The method of the present disclosure can ensure that the tray and the wafer rotate stably together in the low-pressure environment by simultaneously controlling the pressure of the process chamber and the pressure and composition of the cyclone gas.

It should be understood that, the steps may be reordered, added or removed by using the various forms of the flows described above. For example, the steps recorded in the present disclosure can be performed in parallel, in sequence, or in different orders, as long as a desired result of the technical scheme disclosed in the present disclosure can be realized, which is not limited herein.

The foregoing specific implementations do not constitute a limitation on the protection scope of the present disclosure. Those having ordinary skill in the art should understand that, various modifications, combinations, sub-combinations and substitutions may be made according to a design requirement and other factors. Any modification, equivalent replacement, improvement or the like made within the principle of the present disclosure shall be included in the protection scope of the present disclosure.

What is claimed is:

1. An airflow control method for an air flotation cyclone operation of a low-pressure heat treatment device, comprising:
arranging a pressure sensor in a process chamber of the low-pressure heat treatment device, and controlling a pressure of process gas in the process chamber to be 1 to 20 Torrs;
controlling a flow rate of cyclone gas delivered toward a bottom surface of a tray of the low-pressure heat treatment device to be 0.5 to 1.5 L/min by flow control, and controlling accuracy to be within ±0.2 L/min; and
adjusting the flow rate of the cyclone gas so that the tray and a semiconductor workpiece placed on an upper surface of the tray rotate together.

2. The airflow control method of claim 1, wherein the cyclone gas is nitrogen, or oxygen, or a mixture of hydrogen and oxygen.

3. The airflow control method of claim 1, wherein the cyclone gas is a mixture of hydrogen and oxygen and has same composition as the process gas.

4. The airflow control method of claim 3, wherein a flow ratio of hydrogen in the cyclone gas is less than 33% and is not zero.

5. The airflow control method of claim 1, wherein the low-pressure heat treatment device is a remote plasma oxidation treatment device, the pressure in the process chamber is controlled to be within a range of 1 to 8 Torrs by the pressure sensor, the flow rate of the cyclone gas is controlled to be within a range of 0.5 to 1 L/min by a flow controller, and the accuracy is controlled to be within ±0.1 L/min.

6. The airflow control method of claim 1, wherein the low-pressure heat treatment device is a low-pressure free radical oxidation treatment device, the pressure in the process chamber is controlled to be within a range of 5 to 15 Torrs by the pressure sensor, the flow rate of the cyclone gas is controlled to be within a range of 0.5 to 1.5 L/min by a flow controller, and the accuracy is controlled to be within ±0.2 L/min.

7. The airflow control method of claim 1, wherein a rotation speed of the semiconductor workpiece is 40 to 100 revolutions per minute.

8. The airflow control method of claim 7, wherein the rotation speed of the semiconductor workpiece is 60 revolutions per minute.

9. The airflow control method of claim 1, wherein a total flow rate of the process gas is 1 to 60 slm.

10. The airflow control method of claim 1, wherein the cyclone gas delivered toward the bottom surface of the tray of the low-pressure heat treatment device comprises the cyclone gas delivered in one or both of a clockwise direction and a counterclockwise direction.
